(19) United States
(12) Patent Application Publication
(10) Pub. No.: US 2009/0001437 A1
(43) Pub. Date: Jan. 1, 2009

(54) Integrated Circuit Devices Including Recessed Conductive Layers and Related Methods

(75) Inventors: Seok-Jun Won, Seoul (KR); Jung-Min Park, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/142,057

(22) Filed: Jun. 19, 2008

(30) Foreign Application Priority Data
Jun. 27, 2007 (KR) 10-2007-0063796

(51) Int. Cl. H01L 27/108; H01L 21/8242

(52) U.S. Cl. 257/300; 438/239; 257/E27.083; 257/E21.646

(57) ABSTRACT

An integrated circuit device may include a first insulating layer on a substrate with an opening through the first insulating layer. A conductive layer may be on the first insulating layer with the first insulating layer between the conductive layer and the substrate and with the conductive layer set back from the opening. A second insulating layer may be on the conductive layer with the conductive layer between the first and second insulating layers. The second insulating layer may be set back from the opening, and a sidewall of the conductive layer adjacent the opening may be recessed relative to a sidewall of the second insulating layer adjacent the opening. An insulating spacer on portions of the first insulating layer may surround the opening, and the insulating spacer may be on the sidewall of the second insulating layer adjacent the opening so that the insulating spacer is between the sidewall of the second conductive layer and the opening. A conductive contact may be in the opening through the first insulating layer and on portions of the insulating spacer so that the insulating spacer is between the conductive contact and the conductive layer. Related methods are also discussed.

### RELATED APPLICATION

This application claims priority from Korean Patent Application No. 10-2007-0063796 filed on Jun. 27, 2007, in the Korean Intellectual Property Office, the disclosure of which is incorporated herein by reference in its entirety.

### FIELD OF THE INVENTION

The present invention relates to the field of electronics and, more particularly, to integrated circuit electronic devices and related methods.

### BACKGROUND

A semiconductor integrated circuit device may include various microelectronic devices, such as transistors, resistors, capacitors, inductors and/or wirings, integrated on and/or within a semiconductor substrate. Diverse combinations of the microelectronic devices produce a variety of semiconductor integrated circuit devices including various memory devices such as dynamic random access memories (DRAMs), flash memories, static random access memories (SRAMs), phase-change random access memories (PRAMs) and resistive random access memories (RRAMs).

Semiconductor integrated circuit devices are required to become increasingly more integrated in terms of economic and processing efficiency. To integrate a plurality of devices onto a single chip, an inter-layer insulating film may be formed, and the devices may be formed on different layers which are defined by the inter-layer insulating film. In this case, a contact penetrating through the inter-layer insulating film electrically connects the different layers to one another. However, as a design rule is reduced for the improvement of integration density, it is becoming more difficult to form the above devices as designed and electrically connect and/or insulate the devices from one another.

### SUMMARY

According to some embodiments of the present invention, an integrated circuit device may include a first insulating layer on a substrate with the first insulating layer having an opening therethrough. A conductive layer may be on the first insulating layer, the first insulating layer may be between the conductive layer and the substrate, and the conductive layer may be set back from the opening. A second insulating layer may be on the conductive layer so that the conductive layer is between the first and second insulating layers, and the second insulating layer may be set back from the opening. Moreover, a sidewall of the conductive layer adjacent the opening may be recessed relative to a sidewall of the second insulating layer adjacent the opening. An insulating spacer may be on portions of the first insulating layer surrounding the opening and on the sidewall of the second insulating layer adjacent the opening so that the insulating spacer is between the sidewall of the second conductive layer and the opening. A conductive contact may be in the opening through the first insulating layer and on portions of the insulating spacer so that the insulating spacer is between the conductive contact and the conductive layer.

Portions of the insulating spacer may extend between portions of the first and second insulating layers adjacent the conductive layer. A width of a portion of the insulating spacer adjacent the conductive layer in a direction parallel with respect to a surface of the substrate may be greater than a width of a portion of the insulating spacer adjacent the second insulating layer in the direction parallel with respect to the surface of the substrate. The insulating spacer may include silicon nitride, the second insulating layer may include silicon oxy-nitride, and the first insulating layer may include silicon oxide. The first and second insulating layers may include different insulating materials, the first insulating layer and the insulating spacer may include different insulating materials, and the second insulating layer and the insulating spacer may include different insulating materials.

A memory cell access transistor may be on the substrate, and the memory cell access transistor may include first and second source/drain regions of the substrate with the first source/drain region being electrically coupled with the conductive contact. A capacitor storage electrode may be electrically coupled with the second source/drain of the memory cell access transistor. Moreover, a capacitor dielectric layer may be on the capacitor storage electrode, and portions of the conductive layer may be on the capacitor dielectric layer so that the capacitor dielectric layer is between the capacitor storage electrode and the conductive layer.

A bit line may be electrically connected to the conductive contact so that the conductive contact provides electrical coupling between the bit line and the first source/drain of the memory cell access transistor. A third insulating layer may be on the second insulating layer so that the third insulating layer is between the second insulating layer and the bit line, and portions of the conductive contact may extend through the third insulating layer. A width of portions of the conductive contact extending through the third insulating layer may be greater than a width of portions of the conductive contact extending the first insulating layer. Moreover, a capacitor electrode contact may be provided through the second and third insulating layers, and the capacitor electrode contact may be electrically coupled with the conductive layer. In addition, a capacitor electrode wiring layer may be provided on the third insulating layer wherein the capacitor electrode wiring layer is electrically coupled with the conductive layer through the capacitor electrode contact.

The insulating spacer may include a material having a first etch rate with respect to an etchant comprising CHF₃ and/or CF₄, the first insulating layer may include a material having a second etch rate with respect to an etchant comprising CHF₃ and/or CF₄, the second insulating layer may include a material having a third etch rate with respect to an etchant comprising CHF₃ and/or CF₄, and the first etch rate may be lower than the second and third etch rates. An electrically conductive portion of the substrate may be electrically coupled with the conductive contact. Moreover, a third insulating layer may be provided between the substrate and the first insulating layer, and a second conductive contact may be provided through the third insulating layer with the first and second conductive contacts being electrically coupled.

According to other embodiments of the present invention, a method of forming an integrated circuit device may include forming a first insulating layer on a substrate, forming a conductive layer on the first insulating layer so that the first insulating layer is between the conductive layer and the substrate, and forming a second insulating layer on the conductive layer so that the conductive layer is between the first and second insulating layers. A hole may be formed through the second insulating layer and the conductive layer exposing a portion of the first insulating layer, and sidewalls of the conductive layer adjacent the first hole may be recessed relative to sidewalls of the second insulating layer adjacent the first hole. An insulating spacer may be formed on the sidewalls of the second insulating layer and the conductive layer. After forming the insulating spacer, a hole may be formed through the first insulating layer using the insulating spacer as an etch mask, and a conductive contact may be formed in the hole through the first insulating layer an on portions of the insulating spacer.

Forming the hole through the second insulating layer and the conductive layer may include etching the second insulating layer and the conductive layer to expose portions of the first insulating layer, and after etching the second insulating layer and the conductive layer, recessing exposed sidewalls of the conductive layer relative to sidewalls of the second insulating layer. Recessing exposed sidewalls of the conductive layer may include isotropically etching the exposed sidewalls of the conductive layer using an etchant having a first etch rate with respect to the conductive layer and a second etch rate with respect to the second insulating layer, and the first etch rate may be higher than the second etch rate.

Forming the hole through the second insulating layer may include etching the second insulating layer and the conductive layer using an etchant having a first etch rate with respect to the conductive layer and a second etch rate with respect to the second insulating layer, wherein the first etch rate is higher than the second etch rate. The spacer may include silicon nitride, the second insulating layer may include silicon oxy-nitride, and the first insulating layer may include silicon oxide. The first and second insulating layers may include different insulating materials, the first insulating layer and the insulating spacer may include different insulating materials, and the second insulating layer and the insulating spacer may include different insulating materials.

Before forming the first insulating layer, a memory cell access transistor may be formed on the substrate and the memory cell access transistor may include first and second source/drain regions of the substrate with the first source/drain region being electrically coupled with the conductive contact. After forming the first insulating layer, a capacitor storage electrode may be formed with the capacitor storage electrode being electrically coupled with the second source/drain region of the substrate, and a capacitor dielectric layer may be formed on the capacitor storage electrode. Moreover, forming the conductive layer may include forming portions of the conductive layer on the capacitor dielectric layer so that the capacitor dielectric layer is between the capacitor storage electrode and the conductive layer.

A bit line may be formed on the second insulating layer so that the bit line is electrically connected to the conductive contact with the conductive contact providing electrical coupling between the bit line and the first source/drain of the memory cell access transistor. Before forming the bit line, a third insulating layer may be formed on the second insulating layer so that the third insulating layer is between the second insulating layer and the bit line, and portions of the conductive contact may extend through the third insulating layer. A width of portions of the conductive contact extending through the third insulating layer may be greater than a width of portions of the conductive contact extending through the first insulating layer. A capacitor electrode contact may be formed through the second and third insulating layers and electrically coupled with the conductive layer, and a capacitor electrode wiring layer may be formed on the third insulating layer wherein the capacitor electrode wiring layer is electrically coupled with the conductive layer through the capacitor electrode contact.

Before forming the first insulating layer, a third insulating layer may be formed between the substrate and the first insulating layer, and a second conductive contact may be formed through the third insulating layer, and the first and second conductive contacts may be electrically coupled. Moreover, forming the hole through the first insulating layer may include dry etching the first insulating layer using an etchant having an etch rate with respect to the first insulating layer that is higher than an etch rate with respect to the insulating spacer.

Some embodiments of the present invention may provide semiconductor integrated circuit devices providing insulation between a conductive film and a contact penetrating through an insulating film in the vicinity of the conductive film.

Some embodiments of the present invention may also provide methods of fabricating a semiconductor integrated circuit device providing insulation between a conductive film and a contact penetrating through an insulating film in the vicinity of the conductive film, thereby increasing a contact forming margin.

According to some embodiments of the present invention, a semiconductor integrated circuit device may include a lower conductive film pattern, an inter-layer insulating film on the lower conductive film pattern, and an upper conductive film pattern disposed on the inter-layer insulating film. A capping insulating film pattern may be provided on the upper conductive film pattern, a spacer may be provided on a sidewall of the upper conductive film pattern and a sidewall of the capping insulating film pattern, and a contact may penetrate through the inter-layer insulating film to provide electrical connection to the lower conductive film pattern. The contact may be separated from the upper conductive film pattern with the spacer interposed therebetween, and a sidewall of the upper conductive film pattern may be recessed from the sidewall of the capping insulating film pattern, and the spacer may bury a recessed region.

According to other embodiments of the present invention, a semiconductor integrated circuit device may include a cell transistor on a semiconductor substrate, an inter-layer insulating film on the cell transistor and/or a cell capacitor disposed on and/or in the inter-layer insulating film. The cell capacitor may include a storage electrode which is electrically connected to a first source/drain region of the cell transistor, a capacitor dielectric film, and a plate electrode. A capping insulating film pattern may be provided on the cell capacitor and a spacer may be provided on a sidewall of the plate electrode and a sidewall of the capping insulating film pattern. A bitline contact may penetrate through the inter-layer insulating film to provide electrical connection to a second source/drain region of the cell transistor and the bitline contact may be separated from the plate electrode with the spacer interposed therebetween. The sidewall of the plate electrode may be more recessed than the sidewall of the capping insulating film pattern, and the spacer may bury a recessed region.

According to still other embodiments of the present invention, methods of fabricating a semiconductor integrated circuit device may include forming an inter-layer insulating film on a lower conductive film pattern and forming an upper conductive film on the inter-layer insulating film. A capping insulating film may be formed on the upper conductive film and a capping insulating film pattern and an upper conductive film pattern may be formed by patterning the capping insulating film and the upper conductive film. A spacer may be formed on a sidewall of the upper conductive film pattern and a sidewall of the capping insulating film pattern. A contact hole may be formed to penetrate through the inter-layer insulating film and to expose the inter-layer insulating film. The spacer may be used as an etch mask and a contact may be formed in self-alignment with the spacer and burying the contact hole. A sidewall of the upper conductive film pattern may be more recessed than the sidewall of the capping insulating film pattern, and the spacer may bury a recessed region.

According to yet other embodiments of the present invention, methods of fabricating a semiconductor integrated circuit device may include forming a cell transistor on a semiconductor substrate forming an inter-layer insulating film on the cell transistor and forming a storage electrode. The storage electrode may be electrically connected to a first source/drain region of the cell transistor, on and/or in the inter-layer insulating film. A capacitor dielectric film, a conductive film for plate electrodes, and a capping insulating film may be formed on a whole surface of a resultant structure. A capping insulating film pattern and a plate electrode may be formed by patterning the capping insulating film and the upper conductive film. A spacer may be formed on a sidewall of the plate electrode and a sidewall of the capping insulating film pattern. A bitline contact hole may be formed penetrating through the inter-layer insulating film and overlaping a second source/drain region of the cell transistor, using the spacer as an etch mask. A bitline contact may be formed in self-alignment with the spacer, burying the bitline contact hole, and electrically connected to the second source/drain region of the cell transistor. A sidewall of the plate electrode may be more recessed than the sidewall of the capping insulating film pattern, and the spacer may bury a recessed region.

### BRIEF DESCRIPTION OF THE DRAWINGS

The above and other features and advantages of the present invention will become more apparent by describing in detail embodiments thereof with reference to the attached drawings in which:

FIG. 1 is a cross-sectional view of a semiconductor integrated circuit device according to embodiments of the present invention;

FIG. 2 is a cross-sectional view illustrating a shape of a spacer illustrated in FIG. 1;

FIG. 3 is an enlarged view of portion A illustrated in FIG. 1;

FIGS. 4 through 9 are cross-sectional views illustrating operations of fabricating a semiconductor integrated circuit device according to embodiments of the present invention;

FIG. 10 is a cross-sectional view of a semiconductor integrated circuit device according to other embodiments of the present invention;

FIGS. 11 through 19 are cross-sectional views illustrating operations of fabricating a semiconductor integrated circuit device according to still other embodiments of the present invention.

### DETAILED DESCRIPTION

The present invention is described more fully hereinafter with reference to the accompanying drawings, in which embodiments of the present invention are shown. This invention may, however, be embodied in many different forms and should not be construed as limited to the embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity. Like numbers refer to like elements throughout.

It will be understood that when an element or layer is referred to as being “on”, “connected to” or “coupled to” another element or layer, it can be directly on, connected or coupled to the other element, or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly. Also, as used herein, “lateral” refers to a direction that is substantially orthogonal to a vertical direction.

The terminology used herein is for the purpose of describing particular embodiments only, and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. Accordingly, these terms can include equivalent terms that are created after such time. It will be further understood that terms, such as those defined in commonly used dictionaries, should be interpreted as having a meaning that is consistent with their meaning in the present specification and in the context of the relevant art, and will not be interpreted in an idealized or overly formal sense unless expressly so defined herein. All publications, patent applications, patents, and other references mentioned herein are incorporated by reference in their entirety

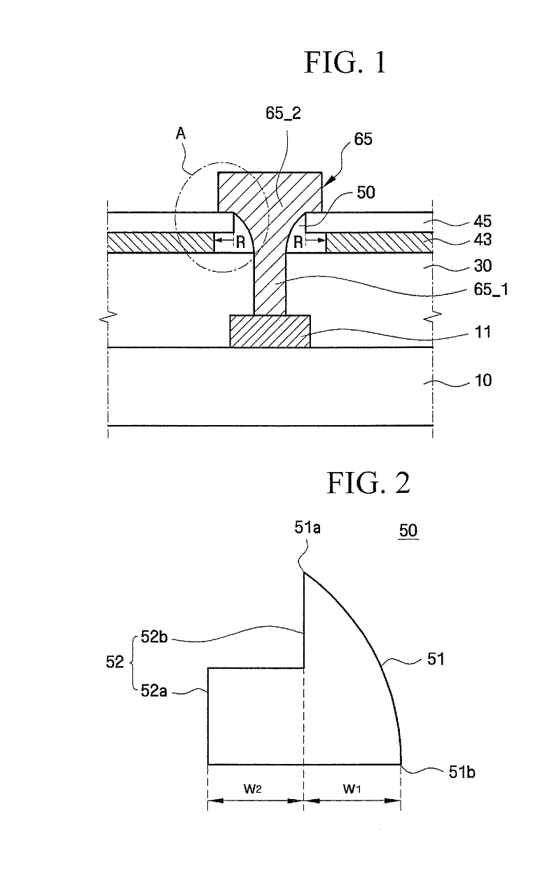

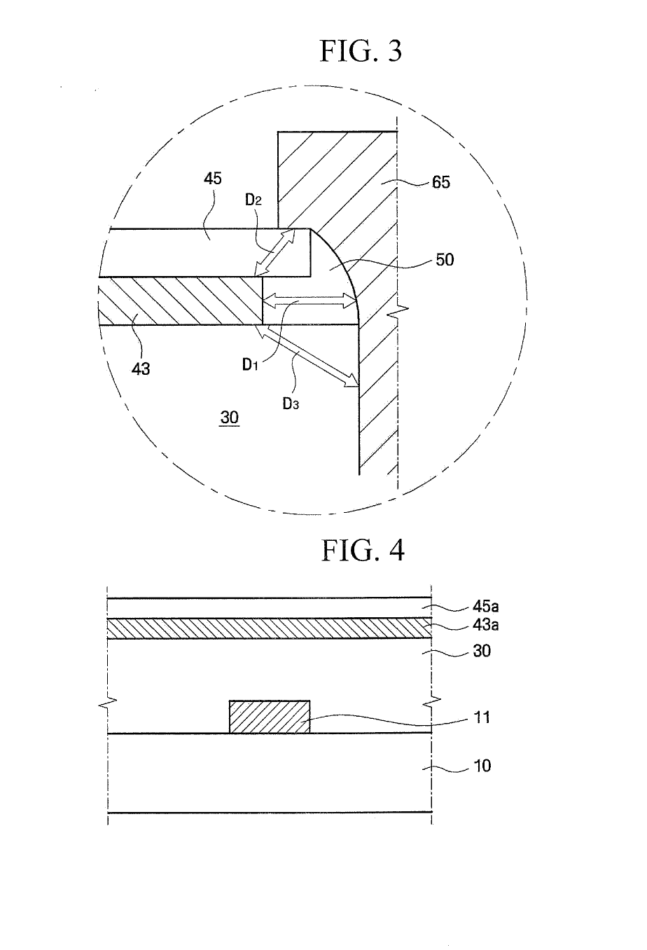

Embodiments of the present invention will be described in more detail with reference to FIGS. 1 through 3. FIG. 1 is a cross-sectional view of a semiconductor integrated circuit device according to some embodiments of the present invention. FIG. 2 is a cross-sectional view illustrating a shape of a spacer 50 illustrated in FIG. 1. FIG. 3 is an enlarged view of portion A illustrated in FIG. 1, and FIG. 3 shows that an upper conductive film pattern 43 is insulated from a contact 65 in a region where they are adjacent to each other.

The semiconductor integrated circuit device of FIG. 1 may include a lower conductive film pattern 11, an inter-layer insulating film 30 on the lower conductive film pattern 11, an upper conductive pattern 43 on the inter-layer insulating film 30, and a capping insulating film pattern 45 on the upper conductive film pattern 43. A spacer 50 may be provided on sidewalls of the upper conductive film pattern 43 and the capping insulating film pattern 45, and the contact 65 may penetrate through the inter-layer insulating film 30 to provide electrical connection to the lower conductive film pattern 11.

The lower conductive film pattern 11 may be formed on and/or within a semiconductor substrate 10. If the lower conductive film pattern 10 is formed on the semiconductor substrate 10, the lower conductive film pattern 10 may be formed immediately on the semiconductor substrate 10, or an insulating film and/or other structures may be interposed between the semiconductor substrate 10 and the lower conductive film pattern 11. If the lower conductive film pattern 11 is formed within the semiconductor substrate 10, the lower conductive film pattern 11 may be formed in the semiconductor substrate 10 through impurity ion implantation. Alternatively, after a portion of the semiconductor substrate 10 is removed, the lower conductive film pattern 11 may be buried in the removed portion of the semiconductor substrate 10.

The lower conductive film pattern 11 may be an electrode, a wordline, a bitline, a connection wiring, a contact, a contact plug formed on the semiconductor substrate 10, and/or an active region (such as a source/drain region), formed in the semiconductor substrate 10. The inter-layer insulating film 30 may be formed on the lower conductive film pattern 11.

The upper conductive film pattern 43 is formed on the inter-layer insulating film 30. Like the lower conductive film pattern 11 described above, the upper conductive film pattern 43 may be an electrode, a wordline, a bitline, a connection wiring, a contact and/or a contact plug. In a stack-type semiconductor integrated circuit device having a plurality of semiconductor substrates stacked, the upper conductive film pattern 43 may be provided as an active region formed in an upper layer.

The capping insulating film pattern 45 may be formed on the upper conductive film pattern 43. The capping insulating film pattern 45 and the spacer 50, which will be described later, may block an electrical contact between the upper conductive film pattern 43 and the contact 65.

Each of the upper conductive film pattern 43 and the capping insulating film pattern 45 may be patterned to not overlap at least a portion of the lower conductive film pattern 11. The spacer 50 is formed on the sidewalls of the patterned upper conductive film pattern 43 and of the patterned capping insulating film pattern 45. The spacer 50 may be formed not to overlap at least a portion of the lower conductive film pattern 11 and may define space in which the contact 65 can be positioned. The spacer 50 may be formed of an insulating material.

The contact 65 may penetrate through the inter-layer insulating film 30 and contact the lower conductive film pattern 1. The contact 65 may extend above the inter-layer insulating film 30 and may occupy the space defined by the spacer 50. Therefore, the spacer 50 is between the contact 65 and the upper conductive film pattern 43. In other embodiments of the present invention, the contact 65 may further extend above the spacer 50, and an upper end of the contact 65 may be connected to another conductive film.

While the contact 65 may be formed on the capping insulating film pattern 45 in FIG. 1, the capping insulating film pattern 45 may be free of the contact 65. That is, the contact 65 may not overlap the capping insulating film pattern 45. In this case, the contact 65 may not contact an entire portion of the spacer 50. Instead, the contact 65 may contact a portion, for example, a lower portion, of the spacer 50. Here, a maximum width of the contact 65 may be less than or equal to the distance between the spacers 50.

A sidewall 51 of the spacer 50 may contact the contact 65, and the contact 65 may be self-aligned with the sidewall 51 of the spacer 50. In this case, the contact 65 may be self-aligned with not only an entire portion, but also a portion of the sidewall 51 of the spacer 50. For example, the contact 65 may be self-aligned with at least a lower portion of the sidewall 51 of the spacer 50.

If the contact 65 is self-aligned with the sidewall 51 of the spacer 50, although the contact 65 is partially misaligned during its formation process, a position at which the contact 65 actually penetrates through the inter-layer insulating film 30 can be predetermined by the spacer 50, or more specifically, by a region in which a lower end 51b of the spacer 50 exposes the inter-layer insulating film 30. Therefore, even if a region in which the contact 65 can be formed is narrow because the upper conductive film patterns 43 are formed close together, the contact 65 can be formed at a precise position. That is, a sufficient process margin (for example, an alignment margin of a photomask) used to form the contact 65 may be provided.

Referring to FIG. 2, a degree to which the sidewall 51 of the spacer 50 protrudes from a vertical line (for example, the sidewall of the capping insulating film pattern 45) toward the contact 65 may remain unchanged or may increase from an upper end 51a of the spacer 50 toward the lower end 51b of the spacer 50. Therefore, a diameter of a section 65_1 of the contact 65 penetrating through the inter-layer insulating film 30 may be equal to or smaller than that of a section 65_2 of the contact 65 which is positioned in the space defined by the spacer 50. The diameter of the section 65_1 of the contact 65 penetrating through the inter-layer insulating film 30 may be less than, for example, approximately 1,000 Å (Angstroms). However, embodiments of the present invention are not limited thereto.

The sidewall of the upper conductive film pattern 43 may be recessed relative to that of the capping insulating film pattern 45. That is, the sidewall of the capping insulating film pattern 45 may protrude further than that of the upper conductive film pattern 43. A recessed region R may be buried (filled) by the spacer 50. Therefore, as illustrated in FIG. 2, a first region 52a of the other sidewall 52 of the spacer 50 (which contacts the sidewall of the upper conductive film pattern 43), may protrude a predetermined distance w₂ further than a second region 52b of the sidewall 52 of the spacer 50 (which contacts the sidewall of the capping insulating film pattern 45).

In this specification, the sentence “the recessed region R is buried (filled) by the spacer 50” denotes not only that the spacer 50 completely buries and occupies an entire portion of the recessed region R, but also that the spacer 50 partially buries and occupies a portion of the recessed region R. While the spacer 50 may completely occupy the entire portion of the recessed region R according to some embodiments disclosed in this specification, it should be understood that embodiments of the present invention may also include a case where the spacer 50 partially buries the recessed region R.

Referring to FIG. 3, a portion of the spacer 50 may be interposed between the contact 65 and the upper conductive film pattern 43 in a first direction D₁ with respect to the upper conductive film pattern 43. The capping insulating film pattern 45 may be interposed between the contact 65 and the upper conductive film pattern 43 in a second direction D₂ The inter-layer insulating film 30 may be interposed between the contact 65 and the upper conductive film pattern 43 in a third direction D₃. Accordingly, the contact 65 may be separated and insulated from the upper conductive film pattern 43 by the spacer 50, the capping insulating film pattern 45, and the inter-layer insulating film 30.

More particularly, insulation between two or more conductors may be determined by a thickness of an insulating film interposed therebetween. For example, insulation in the first direction D₁ of FIG. 3 may be determined by the distance between the sidewall of the contact 65 and that of the upper conductive film pattern 43 having the spacer 50 interposed therebetween, that is, a width (w₁+w₂) of the spacer 50. As described above, since the sidewall of the upper conductive film pattern 43 is recessed from that of the capping insulating film pattern 45, the distance (w₁+w₂) between the upper conductive film pattern 43 and the contact 65 may be increased by the recessed distance w₂ from a distance w₁ between the sidewall of the upper conductive film pattern 43 and that of the capping insulating film pattern 45 which are aligned with each other. Since the recessed region R is filled with the spacer 50, which is formed of, for example, an insulating material, a thickness of an insulating film, i.e., the spacer 50, between the upper conductive film pattern 43 and the contact 65 may be substantially increased by the distance w₂ by which the second region 52a of the sidewall 52 of the spacer 50 protrudes further than the first region 52b. Therefore, electrical insulation between the upper conductive film pattern 43 and the contact 65 in the first direction D₁ may be sufficiently provided, and reliability of the electrical insulation may be enhanced.

The capping insulating film pattern 45 may provide insulation between the contact 65 and the upper conductive film pattern 43 in the second direction D₂. Since the capping insulating film pattern 45 is interposed between the contact 65 and the upper conductive film pattern 43, even if the contact 65 extends onto and thus overlaps the upper conductive film pattern 43, an electrical contact therebetween may be reduced and/or prevented.

For sufficient and reliable insulation, the capping insulating film pattern 45 may have a thickness in the range of approximately 400 Å (Angstroms) to 1,000 Å (Angstroms). This thickness range may be effective not only to stably recess the upper conductive film pattern 43 in a fabrication process, but also to reduce excessive etching in the process of forming the capping insulating film pattern 45 and controlling the degree to which the upper conductive film pattern 43 is recessed. However, it should be understood that the thickness of the capping insulating film pattern 45 according to other embodiments of the present invention is not limited to the above range.

The inter-layer insulating film 30 may insulate the contact 65 from the upper conductive film pattern 43 in the third direction D₃. Referring to FIG. 3, the distance between the contact 65 and the upper conductive film pattern 43 in the third direction D₃ may be greater than that in the first direction D₁. Therefore, if the distance between the contact 65 and the upper conductive film pattern 43 in the first direction D₁ can provide reliable electrical insulation therebetween as described above, it will be understood that the distance in the third direction D₃ can provide sufficiently reliable insulation.

As described above, since the contact 65 and the upper conductive film pattern 43 may be stably and effectively separated and insulated from each other using the spacer 50 with a relatively greater width, the capping insulating film pattern 45, and the inter-layer insulating film 30, even if the contact 65 penetrates between the adjacent upper conductive film patterns 43, insulation between the contact 65 and the upper conductive film patterns 43 may be provided.

FIGS. 4 through 9 are cross-sectional views sequentially illustrating operations of fabricating a semiconductor integrated circuit device according to some embodiments of the present invention. FIGS. 4 through 9 illustrate operations which can be effectively applied to fabricate the semiconductor integrated circuit device of FIG. 1.

Referring to FIG. 4, a lower conductive film pattern 11 is formed on and/or in a semiconductor substrate 10. Then, an inter-layer insulating film 30 may be formed on the lower conductive film pattern 11. The inter-layer insulating film 30 may be formed of, for example, a silicon oxide film.

Next, an upper conductive film 43a and a capping insulating film 45a may be sequentially formed on the inter-layer insulating film 30. Each of the upper conductive film 43a and the capping insulating film 45a may be formed to a thickness in the range of, for example, approximately 400 Å (Angstroms) to 1,000 Å (Angstroms).

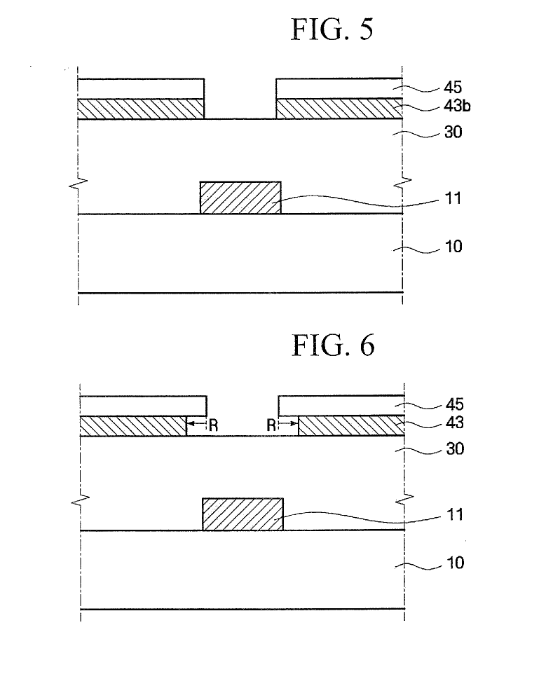

Referring to FIG. 5, a first mask pattern (not shown), which exposes at least a portion of a region where the capping insulating film 45a (shown in FIG. 4), overlaps the lower conductive film pattern 11, is formed on the capping insulating film 45a. Using the first mask pattern as an etch mask, the capping insulating film 45a and the upper conductive film 43a are etched. Consequently, a capping insulating film pattern 45 and a prospective upper conductive pattern 43b are formed. The above etching operation may be an anisotropic etching operation. As a result of the anisotropic etching operation, a sidewall of the etched prospective upper conductive film pattern 43 may be aligned with that of the capping insulating film pattern 45.

Referring to FIG. 6, an upper conductive film pattern 43 may be formed by recessing the prospective upper conductive film pattern 43b more than the capping insulating film pattern 45. The prospective upper conductive film pattern 43b may be recessed in an isotropic etching operation using an etchant which has a higher etch rate for the prospective upper conductive film pattern 43b than an etch rate for the capping insulating film pattern 45. For example, when the prospective upper conductive film pattern 43b is formed of TiN and when the capping insulating film pattern 45 is formed of a silicon oxy-nitride film, an example of an isotropic etching process that can be applied is a wet etching process using an etching etchant including H₂SO₄ and H₂O₂.

According to other embodiments of the present invention, an isotropic etching process (instead of the anisotropic etching process), may be performed in the operation illustrated in FIG. 5. In yet other embodiments of the present invention, the operation illustrated in FIG. 5 may be omitted, and the recessed upper conductive film pattern 43 may be formed using an isotropic etching operation illustrated in FIG. 6.

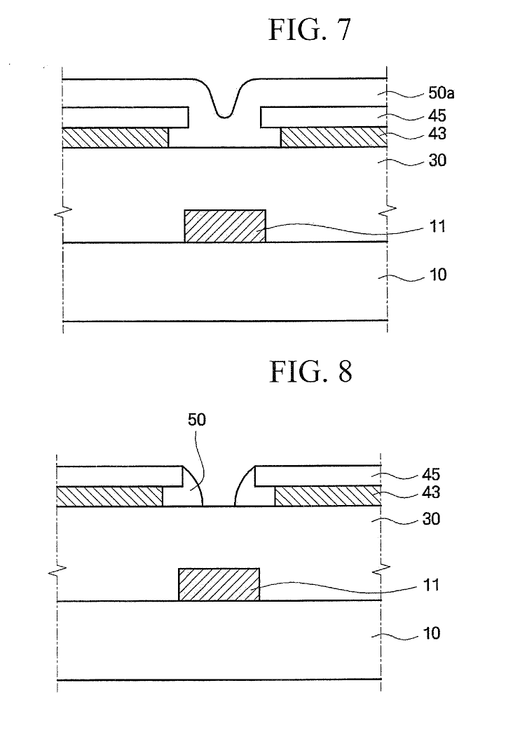

Referring to FIG. 7, an insulating spacer film 50a may be stacked on a whole surface of a resultant structure of FIG. 6. Here, the insulating spacer film 50a may be formed to bury the resultant stricture up to a recessed region R of the upper conductive film pattern 43. The insulating film 50a for spacers may be stacked to a thickness in the range of, for example, approximately 300 Å (Angstroms) to 800 Å (Angstroms).

Referring to FIG. 8, the insulating spacer film 50a may be etched back to form a spacer 50 on a sidewall of the upper conductive film pattern 43 and on a sidewall of the capping insulating film pattern 45.

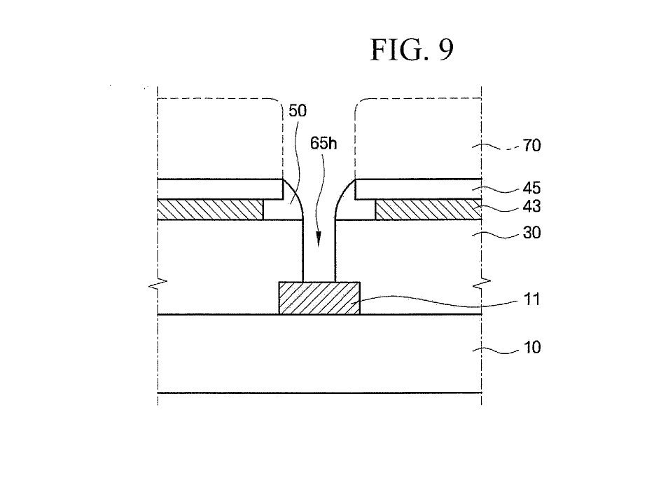

Referring to FIG. 9, the inter-layer insulating film 30 may be etched using the spacer 50 as an etch mask. As a result, a contact hole 65h exposing the lower conductive film pattern 11 may be formed. The contact hole 65h is aligned with a lower end of the spacer 50. Before the inter-layer insulating film 30 is etched, a second mask pattern 70 may be formed on the capping insulating film pattern 45 as indicated by dotted lines in FIG. 9. The second mask pattern 70 may be used as an etch mask together with the spacer 50 to protect the capping insulating film pattern 45.

The above etching operation of FIG. 9 may be a dry etching operation using an etchant that includes CHF₃ and CF₄. Since the spacer 50 is used as an etch mask to etch the inter-layer insulating film 30, a material having a lower etch rate for the etchant (which includes CHF₃ and CF₄), than a material of the inter-layer insulating film 30 may be used to form the spacer 50. In the above etching operation, if the capping insulating film pattern 45 is also to be etched to selectively expose portions of the upper conductive film pattern 43, a material having a lower etch rate for the etchant than a material of the capping insulating film pattern 45 may be used to form the spacer 50. In this case, since a thickness of the capping insulating film pattern 45 is less than that of the inter-layer insulating film 30, a material having a higher etch rate for the etchant than the material of the inter-layer insulating film 30 may be used to form the capping insulating film pattern 45. In an example that satisfies the above conditions, the inter-layer insulating film 30 may be formed of silicon oxide (SiO₂), the spacer 50 may be formed of silicon nitride (SiN), and the capping insulating film pattern 45 may be formed of silicon oxy-nitride (SiON).

Next, a contact 65, which is self-aligned with the spacer 50 and which buries the contact hole 65h, may be formed. Consequently, a semiconductor integrated circuit device as illustrated in FIG. 1 is completed. The contact 65 may be formed of a conductive material providing superior burying characteristics. For example, the contact 65 may be formed of polysilicon and/or tungsten. However, embodiments of the present invention are not limited thereto.

A semiconductor integrated circuit device having a schematic contact and insulation structure of a conductive film and a method of fabricating the semiconductor integrated circuit device according to embodiments of the present invention have been described above. However, embodiments of the present invention may also be applied to semiconductor integrated circuit devices having complicated structures and methods of fabricating such semiconductor integrated circuit devices. One example may be a semiconductor integrated circuit device including dynamic random access memory (DRAM) cells. However, this is merely an example of a semiconductor integrated circuit device having a complicated structure, and embodiments of the present invention are not limited to this example.

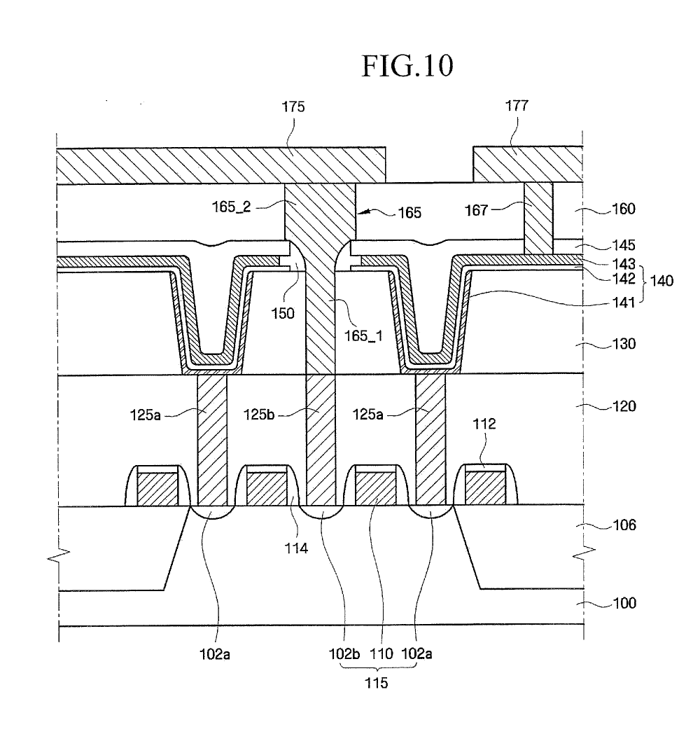

FIG. 10 is a cross-sectional view of a semiconductor integrated circuit device according to other embodiments of the present invention.

Referring to FIG. 10, a device isolation region 106 defines an active region of a semiconductor substrate 100, and a cell transistor 115 is formed in the active region. The cell transistor 115 includes a gate 110, a first source/drain region 102a electrically connected to a cell capacitor 140, and a second source/drain region 102b electrically connected to a bitline 175. In FIG. 10, two cell transistors 115 connected respectively to corresponding cell capacitors 140 may be commonly connected to one bitline 175.

The gate 110 is formed on the semiconductor substrate 100, and the gate 110 may include a conductive film such as a polysilicon film, a metal film and/or a metal silicide film. A gate insulating film (not shown) may be provided between the gate 110 and the semiconductor substrate 100. A gate spacer 114 may be formed on each sidewall of the gate 110. A hard mask 112 may be formed on the gate 110.

The first and second source/drain regions 102a and 102b may be formed by implanting impurity ions into the semiconductor substrate 100. If the semiconductor substrate 100 is a P-type substrate, impurities implanted into the semiconductor substrate 100 may be N-type impurities.

The cell transistor 115 is covered by a lower inter-layer insulating film 120. The lower inter-layer insulating film 120 may be formed of, for example, silicon oxide. Lower contacts 125a for capacitors and lower contacts 125b for bitlines may be provided through the lower inter-layer insulating film 120. The lower contacts 125a for capacitors penetrate the lower inter-layer insulating film 120 and are electrically connected to respective source/drain regions 102a. The lower contact 125b for a bitline penetrates the lower inter-layer insulating film 120 and is electrically connected to source/drain region 102b. According to other embodiments of the present invention, the lower inter-layer insulating film 120, the lower contacts 125a for capacitors, and the lower contact 125b for a bitline may be omitted.

An inter-layer insulating film 130 may be formed on the lower inter-layer insulating film 120. The inter-layer insulating film 130 may define apertures exposing the lower inter-layer insulating film 120 in the vicinity of regions where the lower contacts 125a for capacitors are disposed. Each cell capacitor 140 may include a storage electrode 141, a capacitor dielectric film 142, and a plate electrode 143 sequentially stacked in the respective aperture. The storage electrode 141 may be completely included in the aperture to isolate neighboring cells. Each storage electrode 141 contacts the respective lower contacts 125a and is electrically connected to the respective source/drain region 102a by the lower contacts 125a.

The capacitor dielectric film 142 and the plate electrode 143 may extend from the aperture to a top surface of the inter-layer insulating film 130. Furthermore, because the same voltage is applied to the plate electrode 143 of all cells and because inter-cell node isolation of the cell capacitor 140 has already been provided by isolation of the storage electrodes 141, the plate electrode 143 and the capacitor dielectric film 142 may be provided in an integrated form without regard to the boundaries between cells. Therefore, the plate electrode 143 and the capacitor dielectric film 142 may be formed in the apertures defined by the inter-layer insulating film 130, and also on the top surface of the inter-layer insulating film 130 to cover an entire top surface of the inter-layer insulating film 130. In this case, the plate electrode 143 and the capacitor dielectric film 142 may be patterned and thus removed in the vicinity of a region where a bitline contact 165 penetrates the inter-layer insulating film 130.

A capping insulating film pattern 145 maybe formed on the plate electrode 143. Like the plate electrode 143, the capping insulating film pattern 145 may be formed in the apertures defined by the inter-layer insulating film 130, and also covering an entire top surface of the inter-layer insulating film 130. As described above with reference to FIG. 1, a sidewall of the patterned plate electrode 143 may be recessed from a sidewall of the capping insulating film pattern 145 in the vicinity of a region adjacent to the bitline contact 165. That is, the sidewall of the capping insulating film pattern 145 may protrude further toward the bitline contact 165 than that of the plate electrode 143.

A sidewall of the capacitor dielectric film 142 may also be recessed from that of the capping insulating film pattern 145. However, the sidewall of the capacitor dielectric film 142 may be recessed less than that of the plate electrode 143. Alternatively, the sidewall of the capacitor dielectric film 142 may not be recessed and may be substantially aligned with the sidewall of the capping insulating film pattern 145. A shape of the capacitor dielectric film 142 and a degree to which the capacitor dielectric film 142 is recessed may vary. For example, like the storage electrode 141, the capacitor dielectric film 142 may be provided only in the aperture. In another example, the capacitor dielectric film 142 may extend to a sidewall of a spacer 150 and thus contact the bitline contact 165. In this case, the spacer 150 may be formed on the capacitor dielectric film 142.

The spacers 150 are formed on sidewalls of the plate electrodes 143 and the capping insulating film patterns 145. Each spacer 150 may be substantially identical to the spacer 50 illustrated in FIG. 1. Sidewalls of the spacers 150 may protrude toward the bitline contact 165 and may thus provide space in which the bitline contact 165 can be self-aligned with sidewalls of the spacers 150. In addition, each spacer 150 may bury a region in which the plate electrode 143 is recessed from the sidewall of the capping insulating film pattern 145. Therefore, another sidewall of a spacer 150 may include a first region which contacts a sidewall of the plate electrode 143 and a second region which contacts a sidewall of the capping insulating film pattern 145.

An upper inter-layer insulating film 160 may be formed on the capping insulating film pattern 145. A bitline 175 may be disposed on the upper inter-layer insulating film 160.

The bitline contact 165 penetrates the upper inter-layer insulating film 160 and the inter-layer insulating film 130. An upper end of the bitline contact 165 contacts the bitline 175, and a lower end of the bitline contact 165 contacts the lower contact 125b for a bitline. Therefore, the bitline contact 165 is electrically connected to the second source/drain region 102b by the lower contact 125b for a bitline.

The bitline contact 165 may be self-aligned with a sidewall of the spacer 150. A section 165_1 of the bitline contact 165, which penetrates the inter-layer insulating film 130, may be defined by a region in which a lower end of the spacer 150 exposes the inter-layer insulating film 130. Therefore, a diameter of the section 165_1 of the bitline contact 165, which penetrates the inter-layer insulating film 130, may be determined by a width (or a diameter) of the inter-layer insulating film 130 exposed by the lower end of the spacer 150, regardless of a diameter of a section 165_2 of the bitline contact 165 which penetrates the upper inter-layer insulating film 160.

For example, even when the diameter of the section 165_2 of the bitline contact 165, which penetrates the upper inter-layer insulating film 160, is greater than 1,000 Å (Angstroms), if the width (diameter) of the inter-layer insulating film 130 exposed by the lower end of the spacer 150 is less than 1,000 Å (Angstroms), a diameter of the section 165_1 of the bitline contact 165, which penetrates the inter-layer insulating film 130, may be less than 1,000 Å (Angstroms). Accordingly, even if a mask pattern having a relatively wide exposure region is used to form a bitline contact hole and even if the mask pattern is partially misaligned, a position and diameter of the section 165_1 of the bitline contact 165, which penetrates through the inter-layer insulating film 130, controlled.

A metal wiring 177 used to apply a common voltage to the plate electrode 143 of the cell capacitor 140 may be disposed on the upper inter-layer insulating film 160. In this case, an upper contact 167 may be formed through the upper inter-layer insulating film 160 and the capping insulating film pattern 145. The upper contact 167 may penetrate the upper inter-layer insulating film 160 and the capping film pattern 145 and may electrically connects the metal wiring 177 to the plate electrode 143. As described above, because the same voltage is applied to all cells, a separate upper contact 167 for each capacitor in each cell may not be required.

In FIG. 10, the bitline 175 and the metal wiring 177 may be formed on the same layer. However, this is merely an example. That is, the bitline 175 and the metal wiring 177 may be formed on different layers by providing another inter-layer insulating film (not shown) therebetween.

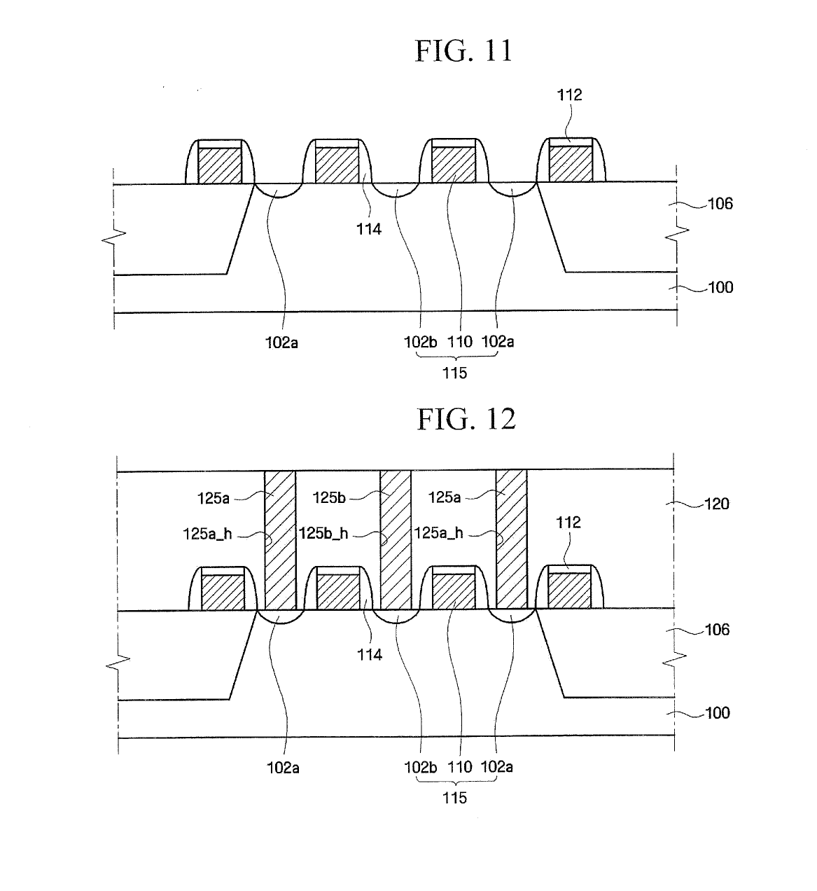

FIGS. 11 through 19 are cross-sectional views illustrating processing operations in methods of fabricating a semiconductor integrated circuit device according to other embodiments of the present invention. FIGS. 11 through 19 illustrate processing operations which can be used to fabricate the semiconductor integrated circuit device of FIG. 10.

Referring to FIG. 11, a device isolation region 106 may be formed in a semiconductor substrate 100, thereby defining an active region. The device isolation region 106 may be formed using shallow trench isolation (STI) or local oxidation of silicon (LOCOS). Then, a gate insulating film (not shown) may be formed on the semiconductor substrate 100 using a thermal oxidation process. Next, gates 110 may be formed on the gate insulating film. Forming the gates 110 may include patterning using hard masks 112 formed on the gates 110 as an etch mask. After the gates 110 are formed, gate spacers 114 may be formed on sidewalls of the gates 110. Then, source/drain regions 102a and source/drain region 102b may be formed by implanting impurity ions into the semiconductor substrate 100. Consequently, cell transistors 115 may be formed on the semiconductor substrate 100.

Referring to FIG. 12, a lower inter-layer insulating film 120 may be formed to cover the cell transistors 115. The lower inter-layer insulating film 120 may be formed of, for example, a silicon oxide film.

Then, lower contact holes 125a h (which expose the first source source/drain regions 102a), and a lower contact hole 125b_{—}h (which exposes the second source/drain region 102b), may be formed by etching the lower inter-layer insulating film 120. Next, the lower contact holes 125a_{—}h and the lower contact hole 125b_{—}h are buried using a conductive film such as polysilicon, thereby completing lower contacts 125a for capacitors and lower contact 125b for bitlines.

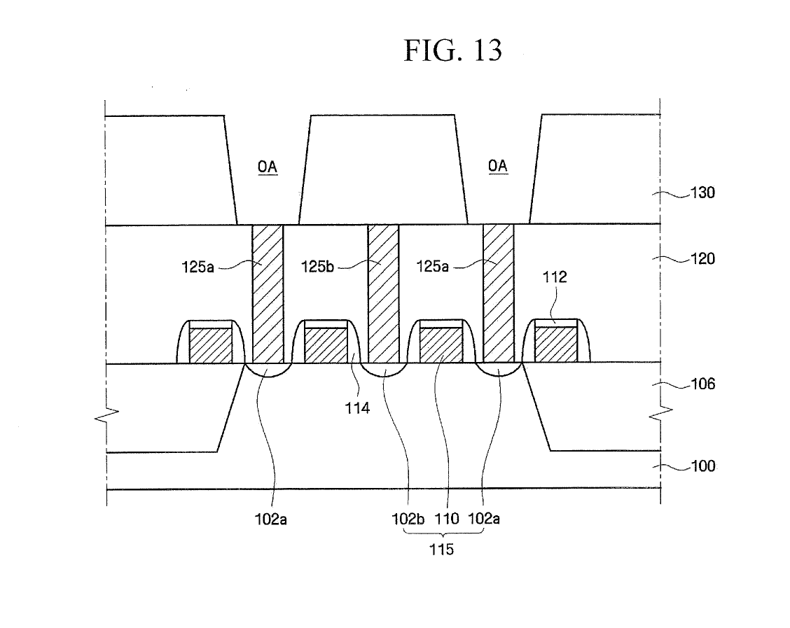

Referring to FIG. 13, an inter-layer insulating film 130 may be formed on the lower inter-layer insulating film 120. Like the lower inter-layer insulating film 120, the inter-layer insulating film 130 may be formed of a silicon oxide film. A thickness of the inter-layer insulating film 130 may be related to a height of substantially formed cell capacitors. That is, a thickness of the inter-layer insulating film 130 may be determined by a height of the designed cell capacitors.

Next, apertures OA, in which the cell capacitors are formed, may be defined by patterning the inter-layer insulating film 130. Here, the apertures OA may be formed to expose at least upper ends of the lower contacts 125a for capacitors.

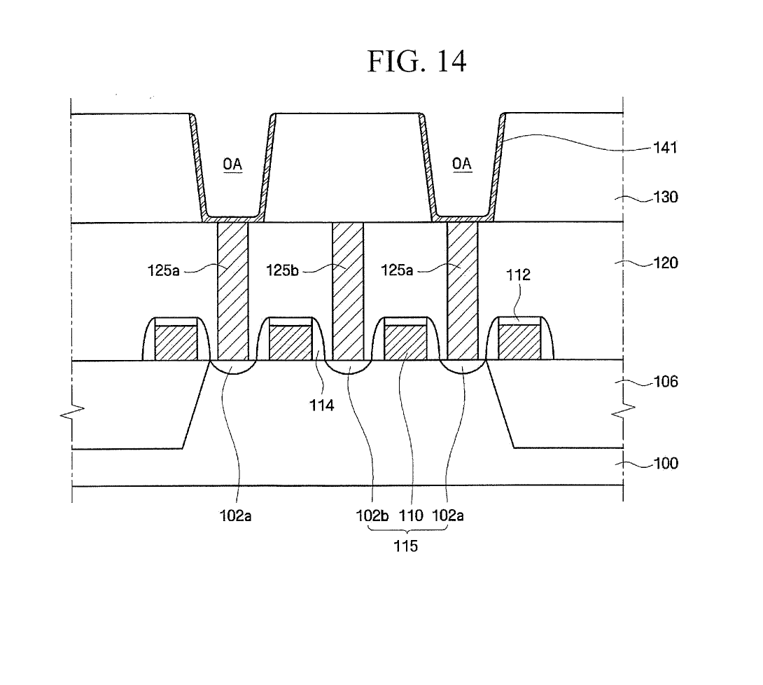

Referring to FIG. 14, storage electrodes 141 may be formed in the apertures OA. A conductive film (not shown) for storage electrodes may be formed on a whole surface of the resultant structure of FIG. 13. The conductive film for storage electrodes may be formed of refractory metal, such as Ti, Ta and/or W, or a refractory metal compound such as TiN, TiSiN, TiAlN, TaN, TaSiN, TaAlN and/or WN.

Portions of the conductive film for storage electrodes that are formed on a top surface of the inter-layer insulating film 130 may be removed from the top surface of the inter-layer insulating film 130 while maintaining portions of the conductive film in the apertures OA, thereby isolating a node of each cell. This node isolation may be performed using a chemical mechanical polishing (CMP) process or an etch-back process. As a result of node isolation, the storage electrodes may be completed in the apertures OA.

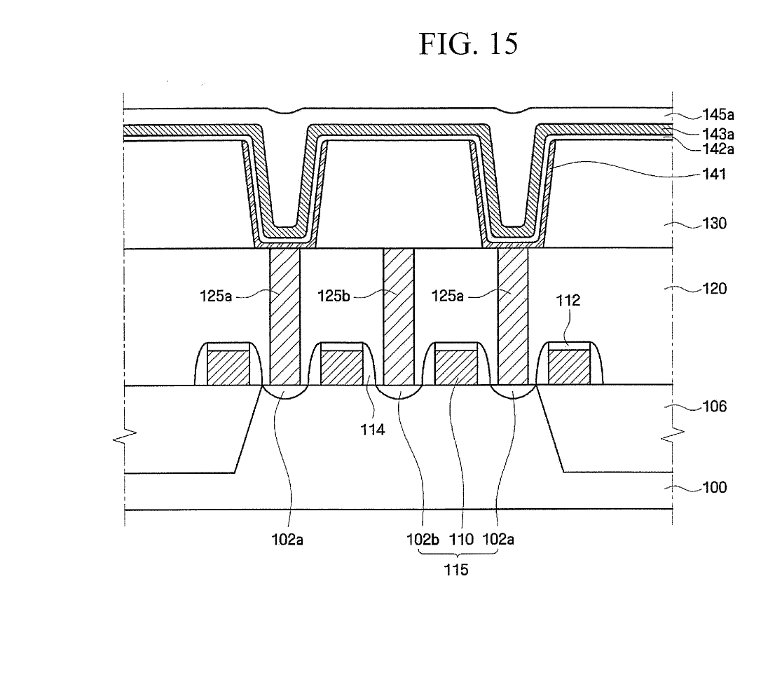

Referring to FIG. 15, a capacitor dielectric film 142a, a conductive film 143a for plate electrodes, and a capping insulating film 145a may be stacked on a whole surface of the resultant structure of FIG. 14.

The capacitor dielectric film 142a may be a single film, such as a silicon oxide film, a silicon nitride film, a silicon oxy-nitride film, or a high dielectric constant (k) metal oxide film, or a stack including a silicon oxide film, a silicon nitride film, a silicon oxy-nitride film, and/or the high-k metal oxide film. Examples of a high-k metal oxide film include a TiO₂ film, a Ta₂O₅ film, an Al₂O₃ film, a BaTiO₃ film, an SrTiO₃ film, a Bi4Ti₃O1₂ film, a PbTiO₃ film, a (Ba, Sr)TiO₃ film, a (Pb, La)(Zr, Ti)O₃ film, and an SrBi₂Ta2O₉ film. However, embodiments of the present invention are not limited thereto.

The conductive film 143a for plate electrodes may be a single film, such as a metal film, a metal oxide film or a metal nitride film, or a stack including a metal film, a metal oxide film and/or a metal nitride film. For example, the conductive film 143a may be formed of Ti, Ta, W, Pt, Ir, Ru, Rh, Os, Pd, RuO₂, IrO₂, (Ca, Sr)RuO_{3,} LaSrCoO_{3,} TiN, TiSiN, TiAlN, TaN, TaSiN, TaAlN, WN, or a combination thereof. However, embodiments of the present invention are not limited thereto. The conductive film 143a for plate electrodes may be formed to a thickness in the range of approximately 400 Å (Angstroms) to 1,000 Å (Angstroms) by, for example, metal organic chemical vapor deposition (MOCVD), physical vapor deposition (PVD), chemical vapor deposition (CVD), plasma enhanced CVD (PECVD), atomic layer deposition (ALD) and/or plasma enhanced ALD (PEALD).

As described above with reference to FIGS. 4 through 9, the capping insulating film 145a may be formed of a silicon oxy-nitride film. In addition, the capping insulating film 145a may be stacked to a thickness in the range of approximately 400 Å (Angstroms) to 1,000 Å (Angstroms).

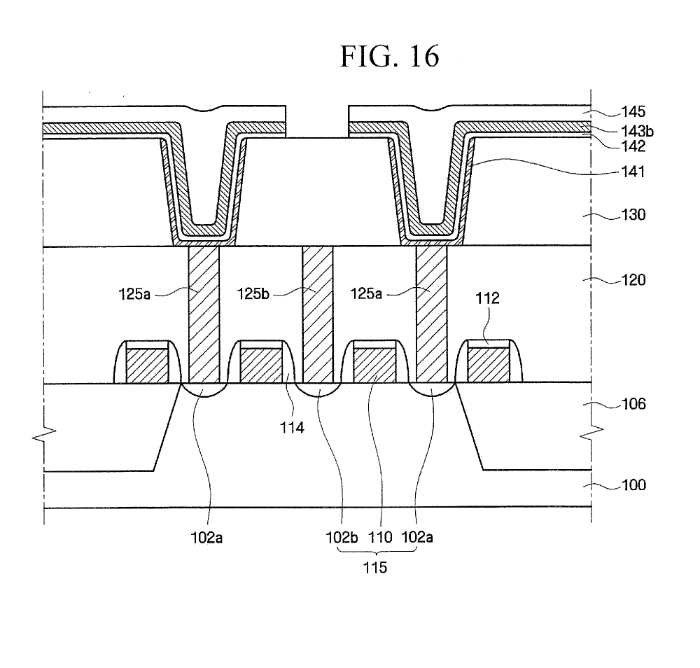

Referring to FIG. 16, a third mask pattern (not shown), which exposes at least a portion of a region where the capping insulating film 145a (shown FIG. 15) overlaps the lower contact 125b for a bitline, may be formed on the capping insulating film 145a. Using the third mask pattern as an etch mask, the capping insulating film 145a and the conductive film 143a for plate electrodes are etched. Consequently, a capping insulating film pattern 145 and a prospective plate electrode 143b may be formed. The above etching process may be an anisotropic etching process. As a result of the anisotropic etching process, a sidewall of the etched prospective plate electrode 143b may be aligned with that of the capping insulating film pattern 145. Here, the capacitor dielectric film 142a may also be etched. As a result, a sidewall of the capacitor dielectric film 142a (shown FIG. 15) may be aligned with that of the capping insulating film pattern 145. In other embodiments of the present invention, the capacitor dielectric film 142 may remain unetched.

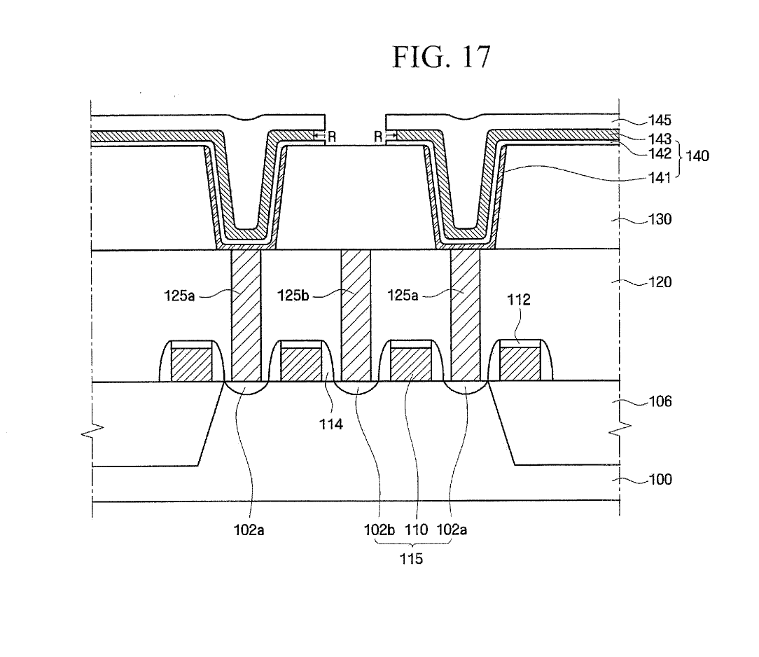

Referring to FIG. 17, a plate electrode 143 may be formed by recessing the prospective plate electrode 143b relative to the capping insulating film pattern 145. The prospective plate electrode 143b may be recessed using an isotropic etch with an etchant that has a higher etch rate for the prospective plate electrode 143b than for the capping insulating film pattern 145. For example, when the prospective plate electrode 143b is formed of TiN and when the capping insulating film pattern 145 is formed of a silicon oxy-nitride film, an example of an isotropic etch is a wet etch using an etchant including H₂SO₄ and H₂O₂.

In other embodiments of the present invention, the isotropic etch (instead of the anisotropic etch), may be performed at FIG. 16. Furthermore, in yet other embodiments of the present invention, the operation illustrated in FIG. 16 may be omitted, and the recessed plate electrode 143 may be formed using the isotropic etch illustrated in FIG. 17.

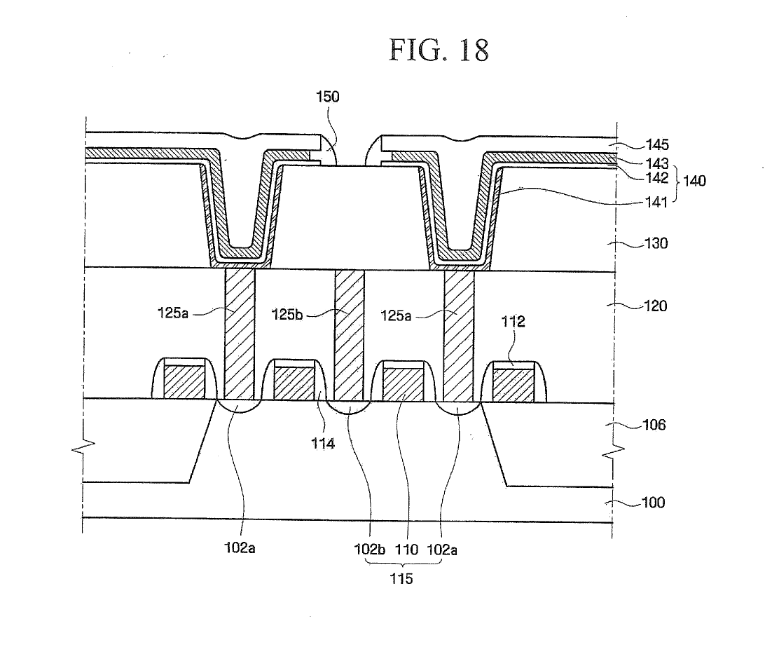

Referring to FIG. 18, a spacer 150 may be formed on sidewalls of the plate electrode 143 and the capping insulating film pattern 145. Methods of forming the spacer 150 may be substantially identical to methods described above with reference to FIGS. 7 and 8, and thus a detailed description thereof will be omitted.

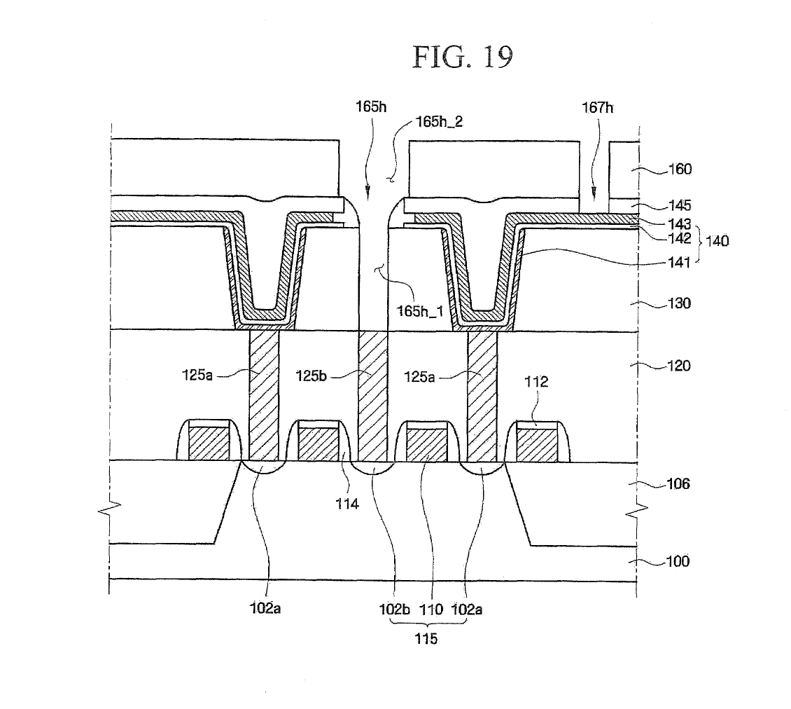

Referring to FIG. 19, an upper inter-layer insulating film 160 may be formed on a whole surface of the resultant structure of FIG. 18. The upper inter-layer insulating film 160 may be formed of a silicon oxide film.

Then, a fourth mask pattern (not shown) defining a bitline contact hole 165h may be formed on the upper inter-layer insulating film 160. The upper inter-layer insulating film 160 and the inter-layer insulating film 130 are etched to form the bitline contact hole 165h which exposes the lower contact 125b for a bitline. While the fourth mask pattern is used to etch the upper inter-layer insulating film 160, the spacer 150 as well as the fourth mask pattern may be used as an etch mask to etch the inter-layer insulating film 130.

More specifically, a region exposed by the fourth mask pattern may include at least a portion of a region where the spacer 140 is formed. Therefore, if the upper inter-layer insulating film 160 is etched using the fourth mask pattern as an etch mask (see the section 165_2), the spacer 150 under the upper inter-layer insulating film 160 may be at least partially etched, and the exposed spacer 150, together with the fourth mask pattern, is used as an etch mask for the inter-layer insulating film 130. Accordingly, a bitline contact hole section 165h_{—}l (which penetrates the inter-layer insulating film 130), is formed to be aligned with a lower end of the spacer 150. Even if the region exposed by the fourth mask pattern is partially misaligned, the bitline contact hole section 165h_{—}l, which penetrates through the inter-layer insulating film 130, can be formed at a position predetermined by the lower end of the spacer 150. Reliability of a position of the bitline contact hole 165h can be increased, and a processing margin can be enhanced. Such effects may become more apparent when a linewidth is reduced as a design rule decreases.

In the operation illustrated in FIG. 19, an upper contact hole 167h for capacitors, which exposes the plate electrode 143, may also be formed, together with the bitline contact hole 165h. In this case, the fourth mask pattern may also define the upper contact hole 167h for capacitors as well as the bitline contact hole 165h. To form the upper contact hole 167h for capacitors, the upper inter-layer insulating film 160 and the capping insulating film pattern 145 may be etched using the fourth mask pattern as an etch mask. This etching process may be performed at the same time as the etching process for forming the bitline contact hole 165h.

The above etch may be a dry etch using an etchant that includes CHF₃ and CF₄. Since the spacer 150 is used as an etch mask to etch the inter-layer insulating film 130 to form the bitline contact hole 165h, a material having a lower etch rate for the etchant (which includes CHF₃ and CF₄) than a material of the inter-layer insulating film 130 may be used to form the spacer 150.

In the operation illustrated in FIG. 19, if the upper contact hole 167h for capacitors is formed together with the bitline contact hole 165h, the capping insulating film pattern 145 is also etched. Therefore, a material having a higher etch rate for the etchant than the material of the spacer 150, which is used as an etch mask, is used to form the capping insulating film pattern 145. Because a thickness of the capping insulating film pattern 145 is less than that of the inter-layer insulating film 130, if the etching process continues for a long period of time to etch the inter-layer insulating film 130 even after the capping insulating film pattern 145 is etched and thus the plate electrode 143 is exposed, the exposed plate electrode 143 may be damaged by the etching etchant. Accordingly, the etching speed of the capping insulating film pattern 145 may be controlled to be lower than that of the inter-layer insulating film 130. In this case, a material of the capping insulating film pattern 145 may have a higher etch rate for the etchant than the material of the inter-layer insulating film 130. In an example that satisfies the above conditions, the inter-layer insulating film 130 may be formed of silicon oxide (SiO₂), the spacer 150 may be formed of silicon nitride (SiN), and the capping insulating film pattern 145 may be formed of silicon oxy-nitride (SiON).

Referring back to FIG. 10, a bitline contact 165 burying the bitline contact hole 165h and/or an upper contact 167 for capacitors, which buries the upper contact hole 167h for capacitors, are formed. Then, a bitline 175 contacting an upper end of the bitline contact 165 and/or a metal wiring 177 contacting an upper end of the upper contact 167 for capacitors may be formed. A section 165_1 of the bitline contact 165, which penetrates the inter-layer insulating film 130, may be self-aligned with the spacer 150. The bitline contact 165 and/or the upper contact 167 for capacitors may be formed of a conductive material having superior burying characteristics. For example, the bitline contact 165 and/or the upper contact 167 may be formed of polysilicon and/or tungsten. However, embodiments of the present invention are not limited thereto.

The bitline contact 165 and the bitline 175 may be formed in a single process. For example, the bitline contact 165 and the bitline 175 may be formed simultaneously by depositing a conductive film to a predetermined thickness in the bitline contact hole 165h until the conductive film fully fills the bitline contact hole 165h and covers a top surface of the upper inter-layer insulating film 160 and then patterning the conductive film. Similarly, the upper contact 167 for capacitors and the metal wiring 177 may be formed simultaneously.

A semiconductor integrated circuit device according to embodiments of the present invention may include a spacer between a conductive film and a contact which is adjacent to the conductive film. The conductive film may be recessed in a direction further from the contact, and the spacer may bury a region in which the conductive film is recessed. Therefore, increased electrical insulation between the conductive film and the contact can be provided.

A method of fabricating a semiconductor integrated circuit device according to embodiments of the present invention may easily recess a sidewall of a conductive film in a direction further from a contact. Since the contact is self-aligned with a spacer formed on the sidewall of the conductive film, a process margin can be provided.

While the present invention has been particularly shown and described with reference to embodiments thereof, it will be understood by those of ordinary skill in the art that various changes in form and details may be made therein without departing from the spirit and scope of the present invention as defined by the following claims.

What is claimed is:

1. An integrated circuit device comprising:
a first insulating layer on a substrate wherein the first insulating layer has an opening therethrough;
a conductive layer on the first insulating layer wherein the first insulating layer is between the conductive layer and the substrate and wherein the conductive layer is set back from the opening;
a second insulating layer on the conductive layer wherein the conductive layer is between the first and second insulating layers, wherein the second insulating layer is set back from the opening, and wherein a sidewall of the conductive layer adjacent the opening is recessed relative to a sidewall of the second insulating layer adjacent the opening;
an insulating spacer on portions of the first insulating layer surrounding the opening and on the sidewall of the second insulating layer adjacent the opening so that the insulating spacer is between the sidewall of the second conductive layer and the opening; and
a conductive contact in the opening through the first insulating layer and on portions of the insulating spacer so that the insulating spacer is between the conductive contact and the conductive layer.

2. An integrated circuit device according to claim 1 wherein portions of the insulating spacer extend between portions of the first and second insulating layers adjacent the conductive layer.

3. An integrated circuit device according to claim 1 wherein a width of a portion of the insulating spacer adjacent the conductive layer in a direction parallel with respect to a surface of the substrate is greater than a width of a portion of the insulating spacer adjacent the second insulating layer in the direction parallel with respect to the surface of the substrate.

4. An integrated circuit device according to claim 1 wherein the insulating spacer comprises silicon nitride, the second insulating layer comprises silicon oxy-nitride, and the first insulating layer comprises silicon oxide.

5. An integrated circuit device according to claim 1 wherein the first and second insulating layers comprise different insulating materials, wherein the first insulating layer and the insulating spacer comprise different insulating materials, and wherein the second insulating layer and the insulating spacer comprise different insulating materials.

6. An integrated circuit device according to claim 1 further comprising:
a memory cell access transistor on the substrate wherein the memory cell access transistor includes first and second source/drain regions of the substrate wherein the first source/drain region is electrically coupled with the conductive contact;
a capacitor storage electrode electrically coupled with the second source/drain of the memory cell access transistor; and
a capacitor dielectric layer on the capacitor storage electrode, wherein portions of the conductive layer are on the capacitor dielectric layer so that the capacitor dielectric layer is between the capacitor storage electrode and the conductive layer.

7. An integrated circuit device according to claim 6 further comprising:
a bit line electrically connected to the conductive contact so that the conductive contact provides electrical coupling between the bit line and the first source/drain of the memory cell access transistor.

8. An integrated circuit device according to claim 7 further comprising:
a third insulating layer on the second insulating layer so that the third insulating layer is between the second insulating layer and the bit line and wherein portions of the conductive contact extend through the third insulating layer.

9. An integrated circuit device according to claim 8 where a width of portions of the conductive contact extending through the third insulating layer is greater than a width of portions of the conductive contact extending the first insulating layer.

10. An integrated circuit device according to claim 8 further comprising:
a capacitor electrode contact through the second and third insulating layers and electrically coupled with the conductive layer; and
a capacitor electrode wiring layer on the third insulating layer wherein the capacitor electrode wiring layer is electrically coupled with the conductive layer through the capacitor electrode contact.

11. An integrated circuit device according to claim 1 wherein the insulating spacer comprises a material having a first etch rate with respect to an etchant comprising CHF₃ and/or CF₄, wherein the first insulating layer comprises a material having a second etch rate with respect to an etchant comprising CHF₃ and/or CF₄, wherein the second insulating layer comprises a material having a third etch rate with respect to an etchant comprising CHF₃ and/or CF₄, and wherein the first etch rate is lower than the second and third etch rates.

12. An integrated circuit device according to claim 1 further comprising:
an electrically conductive portion of the substrate electrically coupled with the conductive contact.

13. An integrated circuit device according to claim 1 further comprising:
a third insulating layer between the substrate and the first insulating layer; and
a second conductive contact through the third insulating layer wherein the first and second conductive contacts are electrically coupled.

14. A method of forming an integrated circuit device, the method comprising:
forming a first insulating layer on a substrate;
forming a conductive layer on the first insulating layer wherein the first insulating layer is between the conductive layer and the substrate;
forming a second insulating layer on the conductive layer wherein the conductive layer is between the first and second insulating layers;
forming a hole through the second insulating layer and the conductive layer exposing a portion of the first insulating layer wherein sidewalls of the conductive layer adjacent the first hole are recessed relative to sidewalls of the second insulating layer adjacent the first hole;
forming an insulating spacer on the sidewalls of the second insulating layer and the conductive layer;
after forming the insulating spacer, forming a hole through the first insulating layer using the insulating spacer as an etch mask; and
forming a conductive contact in the hole through the first insulating layer an on portions of the insulating spacer.

15. A method according to claim 14 wherein forming the hole through the second insulating layer and the conductive layer comprises,
etching the second insulating layer and the conductive layer to expose portions of the first insulating layer, and
after etching the second insulating layer and the conductive layer, recessing exposed sidewalls of the conductive layer relative to sidewalls of the second insulating layer.

16. A method according to claim 15 wherein recessing exposed sidewalls of the conductive layer comprises isotropically etching the exposed sidewalls of the conductive layer using an etchant having a first etch rate with respect to the conductive layer and a second etch rate with respect to the second insulating layer, wherein the first etch rate is higher than the second etch rate.

17. A method according to claim 14 wherein forming the hole through the second insulating layer comprises etching the second insulating layer and the conductive layer using an etchant having a first etch rate with respect to the conductive layer and a second etch rate with respect to the second insulating layer, wherein the first etch rate is higher than the second etch rate.

18. A method according to claim 14 wherein the spacer comprises silicon nitride, the second insulating layer comprises silicon oxy-nitride, and the first insulating layer comprises silicon oxide.

19. A method according to claim 14 wherein the first and second insulating layers comprise different insulating materials, wherein the first insulating layer and the insulating spacer comprise different insulating materials, and wherein the second insulating layer and the insulating spacer comprise different insulating materials.

20. A method according to claim 14 further comprising:
before forming the first insulating layer, forming a memory cell access transistor on the substrate wherein the memory cell access transistor includes first and second source/drain regions of the substrate wherein the first source/drain region is electrically coupled with the conductive contact;
after forming the first insulating layer, forming a capacitor storage electrode wherein the capacitor storage electrode is electrically coupled with the second source/drain region of the substrate; and
forming a capacitor dielectric layer on the capacitor storage electrode;
wherein forming the conductive layer comprises forming portions of the conductive layer on the capacitor dielectric layer so that the capacitor dielectric layer is between the capacitor storage electrode and the conductive layer.

21. A method according to claim 20 further comprising:
forming a bit line on the second insulating layer so that the bit line is electrically connected to the conductive contact with the conductive contact providing electrical coupling between the bit line and the first source/drain of the memory cell access transistor.

22. A method according to claim 21 further comprising:
before forming the bit line, forming a third insulating layer on the second insulating layer so that the third insulating layer is between the second insulating layer and the bit line and wherein portions of the conductive contact extend through the third insulating layer.

23. A method according to claim 22 wherein a width of portions of the conductive contact extending through the third insulating layer is greater than a width of portions of the conductive contact extending through the first insulating layer.

24. A method according to claim 22 further comprising:
forming a capacitor electrode contact through the second and third insulating layers and electrically coupled with the conductive layer; and
forming a capacitor electrode wiring layer on the third insulating layer wherein the capacitor electrode wiring layer is electrically coupled with the conductive layer through the capacitor electrode contact.

25. A method according to claim 14 further comprising:
before forming the first insulating layer, forming a third insulating layer between the substrate and the first insulating layer; and
forming a second conductive contact through the third insulating layer wherein the first and second conductive contacts are electrically coupled.

26. A method according to claim 14 wherein forming the hole through the first insulating layer comprises dry etching the first insulating layer using an etchant having an etch rate with respect to the first insulating layer that is higher than an etch rate with respect to the insulating spacer
